(19) United States
(12) Patent Application Publication
(10) Pub. No.: US 2026/0353969 A1
(43) Pub. Date: Nov. 5, 2026

(54) DISPLAY DEVICE

(71) Applicant: LG Display Co., Ltd., Seoul (KR)

(72) Inventors: Seongwoong JEONG, Paju-si (KR); Minsuk KONG, Paju-si (KR)

(73) Assignee: LG Display Co., Ltd., Seoul (KR)

(21) Appl. No.: 19/660,118

(22) Filed: Apr. 27, 2026

(30) Foreign Application Priority Data
Apr. 30, 2025 (KR) 10-2025-0057438

(51) Int. Cl. H10K 59/38; H10K 59/122; H10K 59/65; H10K 59/80

(52) U.S. Cl. CPC H10K 59/38; H10K 59/122; H10K 59/65; H10K 59/8792

(57) ABSTRACT

A display device according to one embodiment includes a substrate having a display area including a first sub-pixel, a second sub-pixel, and a third sub-pixel, and a non-display area adjacent to the display area. A light-emitting part is disposed in each of the first sub-pixel, the second sub-pixel, and the third sub-pixel on the substrate. A first color filter is on the light-emitting part in the first sub-pixel, a second color filter is on the light-emitting part in the second sub-pixel, and a third color filter is on the light-emitting part in the third sub-pixel. Black matrices are disposed between the second color filter and the third color filter and between the third color filter and the first color filter. An island pattern is disposed between the first color filter and the second color filter, wherein the island pattern includes the same material as the third color filter.

### CROSS-REFERENCE TO RELATED APPLICATION

The present application claims priority to Korean Patent Application No. 10-2025-0057438, filed Apr. 30, 2025, the entire contents of which is incorporated herein for all purposes by this reference.

### BACKGROUND

### Technical Field

The present specification relates to a display device.

### Description of the Related Art

As the information society develops, various demands for display devices for displaying images are increasing, and various types of display devices, such as liquid crystal display (LCD) devices, organic light-emitting diode (OLED) display devices, etc., are utilized.

A display device includes a plurality of pixels and a plurality of switching elements for driving and controlling the pixels.

### BRIEF SUMMARY

The present disclosure describes a display architecture in which a black matrix is selectively omitted at certain sub pixel boundaries and replaced with an island pattern formed from the same material as the blue color filter. The island pattern is positioned, for example, between red and green sub pixels, while the black matrix remains at other boundaries. This non uniform arrangement differs from conventional layouts that use a continuous black matrix between all sub pixels, and enables improved blue color reproduction while maintaining optical separation through the combined filtering effect of adjacent color filters and the island pattern.

The present disclosure further describes forming the black matrix after the color filters rather than before. This sequence allows the black matrix and the island pattern to have reverse tapered profiles and reduces step differences between layers, which in turn reduces light diffraction and external reflection artifacts. In addition, the black matrix is formed with a width smaller than that of the bank layer, thereby increasing the effective opening area and viewing angle, while a bank including a black based material absorbs external light and suppresses visible artifacts.

These features provide a structure in which color filter materials are used both for color selection and for optical control at sub pixel boundaries, while also contributing to process and structural functions. As a result, luminance efficiency, viewing angle, and color balance, particularly in the blue region, are improved, and external light reflection, diffraction effects, and layer related defects are reduced. Various configurations, including different stacking arrangements and relative widths of the island pattern and the black matrix, allow flexibility in implementation.

For example, various embodiments of the present specification are directed to providing a display device capable of increasing an area of an opening region.

Various embodiments of the present specification are also directed to providing a display device with a high viewing angle.

Various embodiments of the present specification are also directed to providing a display device capable of preventing external light reflection (or surface reflection).

Various embodiments of the present specification are also directed to providing a display device capable of preventing diffraction due to external light.

Various embodiments of the present specification are also directed to providing a display device capable of enhancing blue color reproduction.

Various embodiments of the present specification are also directed to providing a low-power display device.

Technical benefits of the present specification are not limited to the above benefits, and other technical benefits may be inferred from the following embodiments.

According to one embodiment, there is provided a display device including a substrate in which a display area including a first sub-pixel, a second sub-pixel, and a third sub-pixel, and a non-display area around the display area, a light-emitting part disposed in each of the first sub-pixel, the second sub-pixel, and the third sub-pixel on the substrate, a first color filter on the light-emitting part in the first sub-pixel, a second color filter on the light-emitting part in the second sub-pixel, and a third color filter on the light-emitting part in the third sub-pixel, a black matrix disposed between the second color filter and the third color filter and between the third color filter and the first color filter, and an island pattern disposed between the first color filter and the second color filter, wherein the island pattern includes the same material as the third color filter.

Detailed matters of other embodiments are included in the detailed description and accompanying drawings.

### BRIEF DESCRIPTION OF THE SEVERAL VIEWS OF THE DRAWINGS

FIG. 1 is a plan view of a display device according to one embodiment.

FIG. 2 is a cross-sectional view illustrating a bent state of the display panel according to FIG. 1.

FIG. 3 is a cross-sectional view along line A-A′ in FIG. 1.

FIG. 4 is a cross-sectional view of a touch part according to FIG. 3.

FIG. 5 is a cross-sectional view along line B-B′ in FIG. 1.

FIG. 6 is a cross-sectional view of the display panel according to another embodiment.

FIG. 7 is a plan view of a display panel according to one embodiment.

FIG. 8 is a cross-sectional view along line C-C′ in FIG. 1.

FIG. 9 is a cross-sectional view of a display device according to a modified example.

FIG. 10 is a cross-sectional view of a display device according to another embodiment.

FIG. 11 is a plan view of a display panel according to another embodiment.

FIG. 12 is a cross-sectional view of a display device according to still another embodiment.

FIG. 13 is a cross-sectional view of the display panel according to still another embodiment.

FIG. 14 is a cross-sectional view of a display panel according to yet another embodiment.

FIG. 15 is a cross-sectional view of a display device according to yet another embodiment.

FIG. 16 is a cross-sectional view of a display device according to yet another embodiment.

FIG. 17 is a cross-sectional view of a display device according to yet another embodiment.

### DETAILED DESCRIPTION

Hereinafter, various embodiments will be described with reference to the accompanying drawings.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals indicate the same components. In some cases, of the various components can be exaggerated for effective description of technical contents.

In the specification, when a certain component (or an area, a layer, a portion, etc.) is described as “on,” “connected,” or “coupled to” another component, it means that the certain component may be directly connected/coupled to another component or still another component may be disposed therebetween.

To further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

The term “and/or” includes all one or more combinations that may be defined by the associated configurations.

Terms such as “first,” “second,” and the like may be used to describe various components, but the components are not limited by the terms. The terms are used only for the purpose of distinguishing one component from another. For example, a first component may be referred to as a second component, and similarly, the second component may also be referred to as the first component without departing from the scopes of various embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” etc., can be used to easily describe the correlation with one element or components and another element or components as shown in the drawings. The spatially relative terms should be understood as including different directions of elements in use or operation in addition to the directions shown in the drawings. For example, in case of turning the element shown in the drawing upside down, an element described as being disposed “below” or “beneath” another element may be disposed “above” another element. Accordingly, the exemplary term “below” may include both downward and upward directions.

It should be understood that terms such as “includes” or “has” are intended to specify the presence of features, numbers, steps, operations, components, parts, or a combination thereof described in the specification and does not preclude the presence or addition possibility of one or more other features, numbers, steps, operations, components, parts, or combinations thereof in advance.

Features of various embodiments of the present specification may be coupled or combined partially or entirely, various technological interworking and driving are made possible, and various embodiments may be implemented independently of each other or implemented together in an associated relationship.

Hereinafter, a display device of the present specification will be described with reference to the accompanying drawings and embodiments as follows.

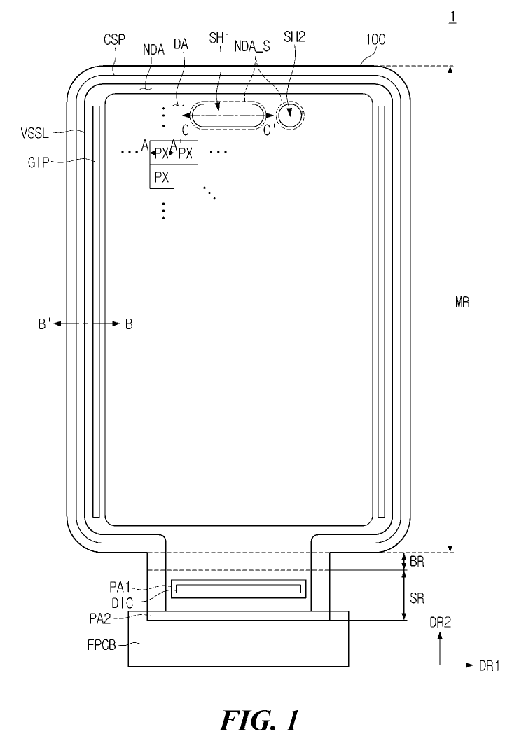

FIG. 1 is a plan view of a display device according to one embodiment.

Referring to FIG. 1, a display device 1 according to one embodiment may include a display panel 100. The display panel 100 may include a display area DA including a plurality of pixels PX and a non-display area NDA around the display area DA. The flat surface shape of the display area DA may have a rectangular shape. However, various embodiments of the present specification are not limited thereto, and the flat surface shape of the display area DA may be a square, circular, elliptical, or other polygonal shapes. For example, the display area DA may have a rectangular shape with rounded corners, but is not limited thereto, and may also have a rectangular shape with angled corners.

In various embodiments, a first direction DR1 and a second direction DR2 are different directions and intersect each other, for example, directions that intersect vertically in a plan view. In FIG. 1, the first direction DR1 may be generally the same as an extension direction of short edges of the display panel 100, and the second direction DR2 may be the same as an extension direction of long edges of the display panel 100. However, the directions described in various embodiments should be understood as indicating relative directions, and various embodiments are not limited to the described directions.

The display area DA may include short edges extending in the first direction DR1 and long edges extending in the second direction DR2. The non-display area NDA may surround the display area DA. The non-display area NDA may be disposed at one side and the other side of the display area DA in the first direction DR1 and one side and the other side of the display area DA in the second direction DR2.

The display panel 100 may further include a sensor non-display area NDA_S and a sensor hole SH surrounded by the sensor non-display area NDA_S. The sensor holes SH1 and SH2 may be surrounded by the display area DA in a plan view. The sensor holes SH1 and SH2 may be, for example, two sensor holes as in FIG. 1, but various embodiments of the present specification are not limited thereto. For example, the sensor hole may be provided as one sensor hole. The two sensor holes SH1 and SH2 may each include a sensor hole in which an infrared sensor is disposed and a sensor hole in which a camera sensor is disposed, but various embodiments of the present specification are not limited thereto. The sensor non-display area NDA_S may be disposed between the sensor holes SH1 and SH2 and the display area DA. The sensor non-display area NDA_S may completely surround the sensor holes SH1 and SH2. A pixel PX may not be disposed in the sensor non-display area NDA_S. In some embodiments, the sensor holes SH1 and SH2 are not disposed, and an infrared sensor or a camera sensor may be disposed in the display area DA. In this case, the number of pixels PX per area of the display area DA in which the infrared sensor or the camera sensor is disposed may be less than the number of pixels PX per area of the display area DA in which the infrared sensor or the camera sensor is not disposed. That is, the display area DA in which the infrared sensor or the camera sensor is disposed may further include a transmissive area.

A gate driving unit GIP may be disposed in the non-display area NDA positioned at the one side and the other side of the display area DA in the first direction DR1. A low-potential voltage line VSSL may be disposed outside the gate driving unit GIP on the non-display area NDA. For example, as illustrated in FIG. 1, the low-potential voltage line VSSL may extend from a printed circuit board FPCB, pass a sub-region SR and a bending region BR, may be positioned outside the gate driving unit GIP on the non-display area NDA, and disposed to surround the display area DA.

The non-display area NDA positioned at the other side of the display area DA in the second direction DR2 may extend further from a central portion of the other side toward the other side of the display area DA in the second direction DR2. A width of the non-display area NDA in the first direction DR1 further extending from the central portion of the other side toward the other side of the display area DA in the second direction DR2 may be smaller than a width of the non-display area NDA in the first direction DR1 adjacent to the other side of the display area DA in the second direction DR2.

The display device 1 may include a main region MR, the sub-region SR, and the bending region BR between the main region MR and the sub-region SR. The display area DA and the non-display area NDA surrounding four surfaces of the display area DA may form the main region MR, and a portion extending from the central portion of the other side toward the other side of the display area DA in the second direction DR2 may form the bending region BR and the sub-region SR. The bending region BR may be disposed between the sub-region SR and the main region MR. The sub-region SR may include a first pad area PA1 and a second pad area PA2 positioned at an end portion of the other side of the sub-region SR in the second direction DR2. The display device 1 may further include a data driving unit DIC and a printed circuit board FPCB. The data driving unit DIC may be disposed in the first pad area PA1, and the printed circuit board FPCB may be attached to the second pad area PA2. A plurality of pads connected to the data driving unit DIC and the printed circuit board FPCB may be disposed in each of the first pad area PA1 and the second pad area PA2. The data driving unit DIC may be configured, for example, in the form of a driving chip (IC), but is not limited thereto. In one embodiment, a case in which the data driving unit DIC is disposed by a chip on plastic method in which the data driving unit DIC is directly mounted on the display panel 100 is described, but various embodiments of the present specification are not limited thereto, and the data driving unit DIC may be disposed by a chip on glass or chip on film method.

The display panel 100 according to one embodiment may further include a crack sensing pattern CSP surrounding the low-potential voltage line VSSL. The crack sensing pattern CSP may be disposed to completely surround the display area DA as illustrated in FIG. 1. For example, the crack sensing pattern CSP may be disposed outside the low-potential voltage line VSSL. However, various embodiments of the present specification are not limited thereto, and a part of the crack sensing pattern CSP may not be disposed in the non-display area NDA of the other side of the display area DA in the second direction DR2.

In some embodiments, the display panel 100 may be a foldable display panel applied to a foldable product. In this case, a folding axis extending in the first direction DR1 or the second direction DR2 may be formed based on FIG. 1. The folding axis may be formed to extend across the display area DA and the non-display area NDA. The foldable display panel may be folded about the folding axis.

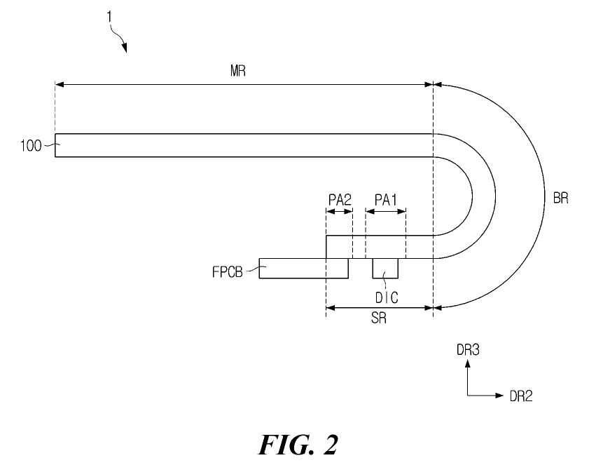

FIG. 2 is a cross-sectional view illustrating a bent state of the display panel according to FIG. 1.

Referring to FIG. 2, the bending region BR of the display panel 100 of the display device 1 according to one embodiment may be bent in a thickness direction (or a third direction DR3). Accordingly, the main region MR and the sub-region SR may overlap each other in the thickness direction. The display panel 100 may be bent such that a lower surface of the main region MR faces an upper surface of the sub-region SR. The printed circuit board FPCB may be attached to an end portion of the sub-region SR.

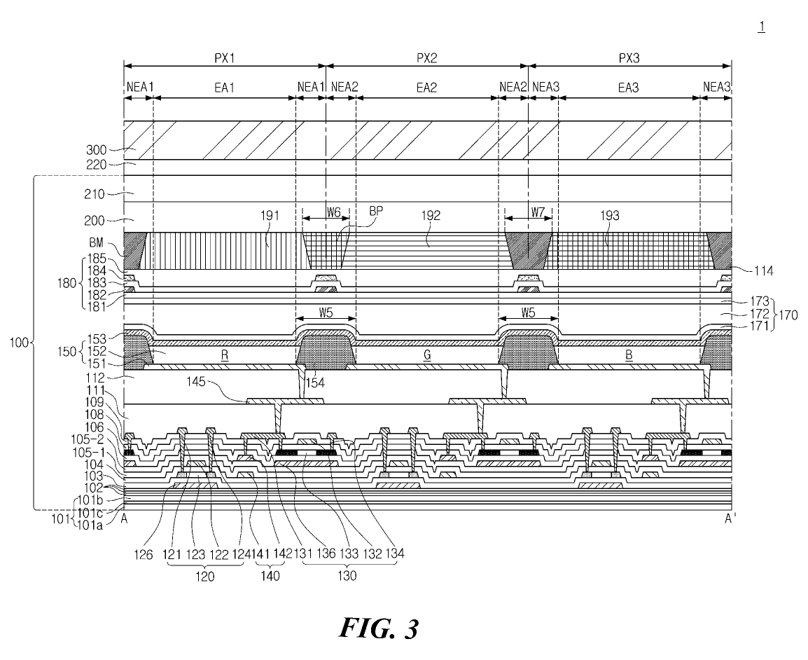

FIG. 3 is a cross-sectional view along line A-A′ in FIG. 1.

Referring to FIG. 3, the pixel PX (see FIG. 1) of the display panel 100 may include a plurality of sub-pixels PX1, PX2, and PX3. A first sub-pixel PX1 may be a red sub-pixel, a second sub-pixel PX2 may be a green sub-pixel, and a third sub pixel PX3 may be a blue sub-pixel, but various embodiments of the present specification are not limited thereto. In some embodiments, the pixel PX further includes a fourth sub-pixel, and the fourth sub-pixel may be a white sub-pixel, but various embodiments of the present specification are not limited thereto.

The first sub-pixel PX1 may include a first light-emitting area EA1 and a first non-light-emitting area NEA1 around the first light-emitting area EA1, the second sub-pixel PX2 may include a second light-emitting area EA2 and a second non-light-emitting area NEA2 around the second light-emitting area EA2, and the third sub-pixel PX3 may include a third light-emitting area EA3 and a third non-light-emitting area NEA3 around the third light-emitting area EA3. That is, the non-light-emitting area NEA1, NEA2, and NEA3 may correspond one-to-one to boundaries between adjacent sub-pixels PX1, PX2, and PX3.

The display panel 100 may include a substrate 101, a first thin-film transistor 120, a second thin-film transistor 130, a light-emitting part 150, an encapsulation part 170, a first black matrix BM1, color filters 191, 192, and 193, a touch part 180, an upper insulating layer 114, a black matrix BM, and a planarization layer OC. The display panel 100 may include at least one panel insulating layer between the substrate 101 and the light-emitting part 150, and at least one touch insulating layer of the touch part 180.

The substrate 101 may include one or more plastic materials. For example, the substrate 101 may be a multi-substrate including a plurality of plastic materials, such as polyimide or the like. For example, the substrate 101 may include a first substrate portion 101a and a second substrate portion 101b each including a plastic material, and a third substrate portion 101c including an inorganic insulation material between the first substrate portion 101a and the second substrate portion 101b, but various embodiments of the present specification are not limited thereto. In some embodiments, the substrate 101 may include glass or quartz, but various embodiments of the present specification are not limited thereto.

The buffer layer 102 may be disposed on the substrate 101. The buffer layer 102 can minimize or delay the diffusion of moisture or oxygen penetrating the substrate 101. The buffer layer 102 may be formed by alternately stacking silicon nitride (SiNₓ) and silicon oxide (SiOₓ) at least once, but various embodiments of the present specification are not limited thereto.

A first light-shielding layer 126 may be disposed on the buffer layer 102. The first light-shielding layer 126 can prevent light from transmitting a first semiconductor layer 123 of the first thin-film transistor 120. For example, the first semiconductor layer 123 may be disposed to overlap the first light-shielding layer 126. The first light-shielding layer 126 may be formed of a single layer or multiple layers made of one of molybdenum (Mo), aluminum (Al), chromium (Cr), nickel (Ni), neodymium (Nd), and copper (Cu) or an alloy thereof, but various embodiments of the present specification are not limited thereto.

A first insulating layer 103 may be disposed on the buffer layer 102 and the first light-shielding layer 126. The first insulating layer 103 can prevent a short circuit between a component of the first thin-film transistor 120 and the first light-shielding layer 126. The first insulating layer 103 may be made of the same material as the buffer layer 102, but various embodiments of the present specification are not limited thereto. For example, the first insulating layer 103 may be made of an inorganic insulation material, such as silicon nitride (SiNₓ) or silicon oxide (SiOₓ), but various embodiments of the present specification are not limited thereto.

The first thin-film transistor 120 may be disposed on the first insulating layer 103. The first thin-film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but various embodiments of the present specification are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor may be formed of the polycrystalline semiconductor layer.

A second insulating layer 104 may be disposed on the first semiconductor layer 123. The second insulating layer 104 may be made of the same material as the first insulating layer 103 and can prevent a short circuit between the first semiconductor layer 123 and another component of the first thin-film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers made of molybdenum (Mo), copper (Cu), titanium (Ti), aluminum (Al), chromium (Cr), gold (Au), nickel (Ni), neodymium (Nd), or a compound thereof, but various embodiments of the present specification are not limited thereto. The first gate electrode 122 may be disposed together with a gate line.

Third insulating layers 105-1 and 105-2 may be disposed on the first gate electrode 122. The third insulating layers 105-1 and 105-2 may be formed by alternately stacking silicon nitride (SiNₓ) and silicon oxide (SiOₓ) at least once, but various embodiments of the present specification are not limited thereto. For example, a 3-1 insulating layer 105-1 may include silicon oxide (SiOₓ), and a 3-2 insulating layer 105-2 may include silicon nitride (SiNₓ), but various embodiments of the present specification are not limited thereto.

The first source electrode 121 and the first drain electrode 124 may be disposed on the third insulating layers 105-1 and 105-2.

The first source electrode 121 and the first drain electrode 124 may be electrically connected to the first semiconductor layer 123 through contact holes. The first source electrode 121 and the first drain electrode 124 may be made of a metallic material. For example, the first source electrode 121 and the first drain electrode 124 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but various embodiments of the present specification are not limited thereto.

The first source electrode 121 and the first drain electrode 124 may be disposed together with the data line. For example, the data line may be made of the same material as the first source electrode 121 and the first drain electrode 124 and formed on the same layer as the first source electrode 121 and the first drain electrode 124, but various embodiments of the present specification are not limited thereto.

The storage electrode 140 may be disposed to be spaced apart from the first thin-film transistor 120. The storage electrode 140 may include a first storage electrode 141 and a second storage electrode 142.

The first storage electrode 141 may be made of the same material as the first gate electrode 122 and disposed on the same layer as the first gate electrode 122, but various embodiments of the present specification are not limited thereto.

The second storage electrode 142 may be disposed on the first storage electrode 141. The second storage electrode 142 may be disposed on the third insulating layers 105-1 and 105-2, and the third insulating layers 105-1 and 105-2 between the first storage electrode 141 and the second storage electrode 142 may be used as a dielectric to generate a capacitance. The second storage electrode 142 may be made of the same material as the first storage electrode 141, but various embodiments of the present specification are not limited thereto.

The second thin-film transistor 130 may be disposed to be spaced apart from the first thin-film transistor 120 and the storage electrode 140. The second thin-film transistor 130 may include a second source electrode 131, a second gate electrode 132, a second semiconductor layer 133, and a second drain electrode 134.

A second light-shielding layer 136 may be disposed on the same layer as the second storage electrode 142.

The second light-shielding layer 136 can prevent light from traveling to the second semiconductor layer 133 similar to the first light-shielding layer 126, thereby extending the lifetime of the second thin-film transistor 130. For example, the second semiconductor layer 133 may be disposed to overlap the second light-shielding layer 136.

A fourth insulating layer 106 may be disposed on the second light-shielding layer 136. The fourth insulating layer 106 may be made of the same material as the first insulating layer 103, the second insulating layer 104, or the third insulating layers 105-1 and 105-2, but various embodiments of the present specification are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but various embodiments of the present specification are not limited thereto.

A fifth insulating layer 108 may be disposed on the second semiconductor layer 133. The fifth insulating layer 108 may be made of the same material as the first insulating layer 103, the second insulating layer 104, the third insulating layers 105-1 and 105-2, or the fourth insulating layer 106, but various embodiments of the present specification are not limited thereto.

The second gate electrode 132 may be disposed on the fifth insulating layer 108.

The second gate electrode 132 may be made of the same material as the first gate electrode 122. For example, the second gate electrode 132 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but various embodiments of the present specification are not limited thereto.

A sixth insulating layer 109 may be disposed on the second gate electrode 132. The sixth insulating layer 109 may be made of the same material as the first insulating layer 103, the second insulating layer 104, the third insulating layers 105-1 and 105-2, the fourth insulating layer 106, or the fifth insulating layer 108, but various embodiments of the present specification are not limited thereto.

The first source electrode 121, the first drain electrode 124, the second source electrode 131, and the second drain electrode 134 may be disposed on the sixth insulating layer 109.

The second source electrode 131 and the second drain electrode 134 may be formed of the same material as the first source electrode 121 and the first drain electrode 124 and disposed on the same layer as the first source electrode 121 and the first drain electrode 124, but various embodiments of the present specification are not limited thereto. For example, the second source electrode 131 and the second drain electrode 134 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but various embodiments of the present specification are not limited thereto. For example, the second source electrode 131 may be electrically connected to the second storage electrode 142. The second source electrode 131 may pass through the sixth insulating layer 109, the fifth insulating layer 108, and the fourth insulating layer 106 and may be electrically connected to the second storage electrode 142.

The first thin-film transistor 120 may be a switching transistor, and the second thin-film transistor 130 may be a driving transistor, but various embodiments of the present specification are not limited thereto.

The first protective layer 111 may be disposed on the first source electrode 121 and the first drain electrode 124.

The first protective layer 111 may planarize an upper portion of the first thin-film transistor 120 and protect the first thin-film transistor 120. The first protective layer 111 may be made of an organic material. For example, the first protective layer 111 may be made of an organic material including an acrylic resin, an epoxy resin, a phenolic resin, a polyamide resin, or a polyimide resin, but various embodiments of the present specification are not limited thereto.

A second protective layer 112 may be disposed on the first protective layer 111. The second protective layer 112 may be made of the same material as the first protective layer 111, but various embodiments of the present specification are not limited thereto.

In some embodiments, a third protective layer may be further disposed on an upper surface of the second protective layer 112, but various embodiments of the present specification are not limited thereto.

A connection electrode 145 may be disposed between the first protective layer 111 and the second protective layer 112.

When the third protective layer is further disposed, a first electrode 151 may be connected to the connection electrode 145 through the third protective layer and the second protective layer 112.

The connection electrode 145 may electrically connect the first thin-film transistor 120 to the light-emitting part 150. The connection electrode 145 may be made of the same material as the first source electrode 121 and the first drain electrode 124, but various embodiments of the present specification are not limited thereto.

The connection electrode 145 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but various embodiments of the present specification are not limited thereto.

The light-emitting part 150 may be disposed on the second protective layer 112. The light-emitting part 150 may include the first electrode 151, an organic layer 152, and a second electrode 153.

The first electrode 151 may be disposed on the second protective layer 112. The first electrode 151 may be electrically connected to the first thin-film transistor 120 via a contact hole formed in the second protective layer 112. The first electrode 151 may perform an anode function, but various embodiments of the present specification are not limited thereto. The first electrode 151 may be a reflective electrode that reflects light, but various embodiments of the present specification are not limited thereto. The first electrode 151 may include a metallic material with high reflectance, such as a stacked structure (Ti/Al/Ti) of aluminum (Al) and titanium (Ti), a stacked structure (ITO/Al/ITO) of aluminum (Al) and indium tin oxide (ITO), or an APC alloy and may be formed of a single layer or multiple layers, but various embodiments of the present specification are not limited thereto.

The organic layer 152 may be disposed on the first electrode 151. The organic layer 152 may include one or more light-emitting structures (or light-emitting elements or elements) stacked on the first electrode 151 in the order or reverse order of a hole transfer layer and an electron transfer layer. For example, the hole transfer layer may include a hole transporting layer, a hole injecting layer, an electron shielding layer, a p-type charge generation layer, etc., but various embodiments of the present specification are not limited thereto. For example, the electron transfer layer may include an electron transporting layer, an electron injecting layer, a hole shielding layer, an n-type charge generation layer, etc., but various embodiments of the present specification are not limited thereto. The organic layer 152 may be an organic light-emitting layer, an inorganic light-emitting layer, a quantum dot light-emitting layer, a micro light-emitting diode, a micro mini light-emitting diode, etc., but various embodiments of the present specification are not limited thereto. For example, the organic layer 152 of the display panel 100 according to one embodiment of the present specification may include an organic light-emitting layer. The organic layer 152 may include a red light-emitting layer, a green light-emitting layer, and a blue light-emitting layer. The organic layer 152 may be a white light-emitting layer, but various embodiments of the present specification are not limited thereto. The organic layer 152 may be separately disposed in each of the sub-pixels PX1, PX2, and PX3, as illustrated in FIG. 3, but various embodiments of the present specification are not limited thereto, and the organic layer 152 may be integrally disposed across each of the sub-pixels PX1, PX2, and PX3.

The second electrode 153 may be disposed on the organic layer 152. The second electrode 153 may perform a cathode function, but various embodiments of the present specification are not limited thereto. The second electrode 153 may be a transparent electrode that transmits light, but various embodiments of the present specification are not limited thereto. For example, the second electrode 153 may include a transparent conductive material, such as ITO or IZO, or a metal that transmits visible light, but various embodiments of the present specification are not limited thereto.

A bank 154 may be disposed to expose the first electrode 151. The bank 154 may be disposed to cover an edge portion (or a periphery) of the first electrode 151. The banks 154 may be disposed at the boundaries NEA1, NEA2, and NEA3 between adjacent sub-pixels PX1, PX2, and PX3.

The bank 154 may include an organic insulation material. For example, the bank 154 may include a transparent organic insulation material. For example, the bank 154 may be a transparent bank. However, various embodiments of the present specification are not limited thereto, and the bank 154 may also be a black bank including a black-based organic insulation material. The bank 154 may be made of a material including black pigment or black dye, or an organic material, such as a benzocyclobutene resin, a polyimide resin, an acrylic resin, a photosensitive polymer, etc., but various embodiments of the present specification are not limited thereto.

A spacer may be further disposed on the bank 154. The spacer may be formed of the same material as the bank 154, but various embodiments of the present specification are not limited thereto. For example, the spacer may be a transparent bank, but is not limited thereto, and may be formed of the same material as the bank 154. For example, the spacer may be disposed on at least one of the boundaries between the first to third sub-pixels PX1, PX2, and PX3, but various embodiments of the present specification are not limited thereto. The bank 154 and the spacer may be made of the same material and formed simultaneously through a halftone mask, but various embodiments of the present specification are not limited thereto.

The organic layer 152 may be disposed on the first electrode 151 and the bank 154. The second electrode 153 may be disposed on the organic layer 152.

The encapsulation part 170 may be disposed on the second electrode 153. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 on the second encapsulation layer 172. The encapsulation part 170 may include one or more inorganic insulation material layers and one or more organic material layers. For example, the first encapsulation layer 171 and the third encapsulation layer 173 may include an inorganic insulation material, and the second encapsulation layer 172 may include an organic material, but various embodiments of the present specification are not limited thereto.

The display panel 100 according to one embodiment may further include a black matrix BM. The black matrix BM may include a black-based material. For example, the black matrix BM may include an organic or inorganic insulation material including a black-based material.

The black matrix BM may be disposed at the boundaries between adjacent sub-pixels PX1, PX2, and PX3. For example, the black matrix BM may be disposed in the non-light-emitting areas NEA1, NEA2, and NEA3. The black matrix BM can prevent a sensor electrode and a bridge electrode, which will be described below, from being visible from the outside.

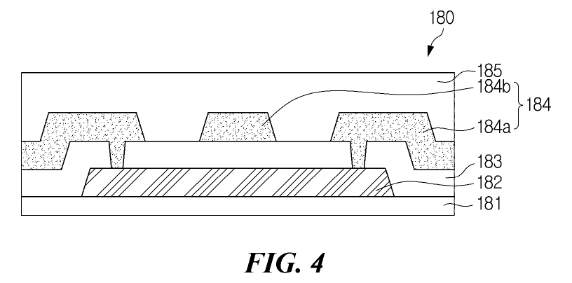

The touch part 180 may be disposed on the encapsulation part 170. The touch part 180 may include a touch buffer layer 181, a first touch conductive layer, a first touch insulating layer 183, a second touch conductive layer, and a second touch insulating layer 185. The touch part 180 will be described with reference to FIG. 4.

FIG. 4 is a cross-sectional view of a touch part according to FIG. 3.

Referring to FIGS. 3 and 4, the touch buffer layer 181 may be disposed on the encapsulation part 170. For example, the touch buffer layer 181 may be disposed on the third encapsulation layer 173. The touch buffer layer 181 may be made of the same material as the buffer layer 102, but various embodiments of the present specification are not limited thereto.

The first touch conductive layer may be disposed on the touch buffer layer 181. The first touch conductive layer may include a bridge electrode 182. The bridge electrode 182 and a sensor electrode 184 to be described below may be disposed at each of the boundaries between adjacent sub-pixels PX1, PX2, and PX3. For example, the bridge electrode 182 and the sensor electrode 184 may be disposed in the non-light-emitting areas NEA1, NEA2, and NEA3. The bridge electrode 182 and the sensor electrode 184 may overlap the black matrix BM to be described below in the thickness direction. The black matrix BM may cover the bridge electrode 182 and the sensor electrode 184. Accordingly, the bridge electrode 182 and the sensor electrode 184 can be prevented from being visible from the outside.

A first touch insulating layer 183 may be disposed on the first touch conductive layer. The first touch insulating layer 183 can prevent a short circuit between the first touch conductive layer and the second touch conductive layer. The first touch insulating layer 183 may include an inorganic insulation material or an organic insulation material. In some embodiments, the first touch insulating layer 183 may include two or more layers, but various embodiments of the present specification are not limited thereto.

The second touch conductive layer may be disposed on the first touch insulating layer 183. The second touch conductive layer may include a first sensor electrode 184a and a second sensor electrode 184b. The sensor electrode 184 may include the first sensor electrode 185a extending in the first direction DR1 (see FIG. 1) and the second sensor electrode 185b extending in the second direction DR2 (see FIG. 1) different from the first direction DR1.

The second touch insulating layer 185 may be disposed on the second touch conductive layer. The second touch insulating layer 185 may include an organic insulation material or an inorganic insulation material.

The sensor electrode 184 and the bridge electrode 182 may include a metallic material. For example, the sensor electrode 185 and the bridge electrode 182 may be made of titanium (Ti), nickel (Ni), aluminum (Al), or an alloy thereof and formed of a triple layer, such as titanium (Ti)/aluminum (Al)/titanium (Ti), but various embodiments of the present specification are not limited thereto.

An upper insulating layer may be further disposed on the second touch insulating layer 185, but various embodiments of the present specification are not limited thereto.

The color filters 191, 192, and 193 may be disposed on the second touch insulating layer 185. The color filters 191, 192, and 193 may be disposed on the first to third sub-pixels PX1, PX2, and PX3, respectively, and may block specific colors from light emitted from the light-emitting area EA1, EA2, and EA3 of the sub-pixels PX1, PX2, and PX3. A first color filter 191 may be provided to block light of other colors not including red (R) light. In this case, the first color filter 191 may be provided as a red color filter. A second color filter 192 may be provided to block light of other colors not including green (G) light. In this case, a second color filter 192 may be provided as a green color filter. A third color filter 193 provided in the third sub-pixel PX3 may be provided to block light of other colors not including blue (B) light. In this case, the third color filter 193 may be provided as a blue color filter. However, various embodiments of the present specification are not limited thereto. The color filters 191, 192, and 193 may be disposed on the light-emitting areas EA1, EA2, and EA3, respectively, and may extend to portions of the non-light-emitting areas NEA1, NEA2, and NEA3, respectively, but various embodiments of the present specification are not limited thereto. The color filters 191, 192, and 193 may be spaced apart from each other at the boundaries between the sub-pixels PX1, PX2, and PX3.

According to various embodiments of the present specification, the black matrix BM may be formed after the first to third color filters 191 to 193 are formed.

According to various embodiments of the present specification, a width of the black matrix BM may be smaller than a width of the bank 154. For example, a separation distance between the black matrix BM positioned in the first and second non-light-emitting areas NEA1 and NEA2 and the black matrix BM positioned in the second and third non-light-emitting areas NEA2 and NEA3 may be greater than a separation distance between the bank 154 positioned in the first and second non-light-emitting areas NEA1 and NEA2 and the bank 154 positioned in the second and third non-light-emitting areas NEA2 and NEA3. Ends of the banks 154 may be aligned with the boundaries between the light-emitting areas EA1, EA2, and EA3 and the non-light-emitting areas NEA1, NEA2, and NEA3, but various embodiments of the present specification are not limited thereto. In the case of the display panel 100 according to one embodiment, since the bank 154 may include a black-based material and the width of the black matrix BM is smaller than the width of the bank 154, light emitted from the light-emitting areas EA1, EA2, and EA3 may be emitted upward with a viewing angle greater than an opening exposed by the black matrix BM. Accordingly, it is possible to prevent a reduction in luminance according to a viewing angle. However, when the width of the black matrix BM is smaller than the width of the bank 154 and the bank 154 is made of only a transparent material, externally incident light may be reflected by the bank 154, thereby causing a ring-shaped artifact to be perceived. However, in the display panel 100 according to one embodiment, the externally incident light may be absorbed or blocked by the bank 154 including a black-based material, thereby preventing the occurrence of the ring-shaped artifact and preventing external light reflection (or surface reflection).

For example, the black matrix BM may be disposed at the boundary between the second sub-pixel PX2 and the third sub-pixel PX3 and the boundary between the third sub-pixel PX3 and the first sub-pixel PX1. The black matrix BM may not be disposed at the boundary between the first sub-pixel PX1 and the second sub-pixel PX2. An island pattern BP may be disposed at the boundary between the first sub-pixel PX1 and the second sub-pixel PX2. The island pattern BP may include the same material as the third color filter 193. That is, the island pattern BP may transmit blue light and block red and green light. According to one embodiment, by omitting the black matrix BM and arranging the island pattern BP that transmits blue light at the boundary between the first sub-pixel PX1 and the second sub-pixel PX2, the overall blue color reproduction can be enhanced. In addition, at the boundary between the first sub-pixel PX1 and the second sub-pixel PX2, the first color filter 191 that transmits only red light, the island pattern BP, and the second color filter 192 that transmits only green light are sequentially disposed from the left side, such that the island pattern BP and the surrounding color filters 191 and 192 may perform the function of the black matrix BM.

According to the present embodiment, since the black matrix BM is formed after the color filters 191, 192, and 193 are formed, the black matrix BM may have a reverse-tapered shape. In addition, for example, the first color filter 191 may be formed, the second color filter 192 may be formed, and then the third color filter 193 may be formed, and the island pattern BP may be formed together with the third color filter 193. Accordingly, the island pattern BP may also have a reverse-tapered shape.

The black matrix BM may be in direct contact with side surfaces of the organic layers 152 disposed in the adjacent second and third sub-pixels PX2 and PX3, and side surfaces of the organic layers 152 disposed in the adjacent third and first sub-pixels PX3 and PX1.

The island patterns BP may be in direct contact with the side surfaces of the organic layers 152 disposed in the adjacent first and second sub-pixels PX1 and PX2.

In the display device 1 according to one embodiment, since the black matrix BM is formed after the color filters 191, 192, and 193 are formed, it is possible to prevent the occurrence of steps between the color filters 191, 192, and 193 in the non-light-emitting areas NEA1, NEA2, and NEA3 due to the existing black matrix. When the steps occur between the color filters 191, 192, and 193, external light may be diffracted or reflected at the steps, thereby being visible from the outside. However, in the display device 1 according to one embodiment, since the step does not occur, image quality can be improved.

FIG. 3 illustrates that the black matrix BM and the island pattern BP do not overlap upper surfaces of adjacent color filters 191, 192, and 193 and are in contact with only the side surfaces thereof, but various embodiments of the present specification are not limited thereto. For example, the black matrix BM and the island pattern BP may be disposed to extend to portions of the upper surfaces of adjacent color filters 191, 192, and 193.

In addition, FIG. 3 illustrates that the cross-sectional shape of the black matrix BM and the island pattern BP is a reverse-tapered trapezoid, but various embodiments of the present specification are not limited thereto, and the cross-sectional shape may also be a shape with a concave center (e.g., a V-shape or a U-shape).

In addition, since the black matrix BM is formed after the color filters 191, 192, and 193 are formed, an area of the black matrix BM may be intentionally reduced, and areas of the opening regions (or the light-emitting areas EA1, EA2, and EA3) can be increased.

In addition, by reducing the area of the black matrix BM, the viewing angle can be increased.

In addition, as described above, the viewing angle can be increased by designing the width of the black matrix BM to be smaller than the width of the bank 154.

The planarization layer 200 may be disposed on the color filters 191, 192, and 193, the black matrix BM, and the island pattern BP. The planarization layer 200 may include an organic insulation material, but various embodiments of the present specification are not limited thereto. The planarization layer 200 may be in direct contact with the color filters 191, 192, and 193, the black matrix BM, and the island pattern BP.

An upper insulating layer 210 may be disposed on the planarization layer 200. The upper insulating layer 210 may include an organic insulation material, but various embodiments of the present specification are not limited thereto.

A cover layer 300 may be disposed on the upper insulating layer 210. The cover layer 300 may include glass or plastic, but various embodiments of the present specification are not limited thereto. The cover layer 300 may protect the display panel 100.

A bonding layer 220 may be disposed between the cover layer 300 and the display panel 100 (or the upper insulating layer 210). The bonding layer 220 may include, for example, an adhesive material having a gray-based color. For example, the bonding layer 220 may be formed by mixing a gray-based color material with an optically transparent adhesive (OCA), but various embodiments of the present specification are not limited thereto. According to one embodiment, by arranging the bonding layer 220 having a gray-based color between the cover layer 300 and the display panel 100, the entry of external light into the display panel 100 can be partially reduced.

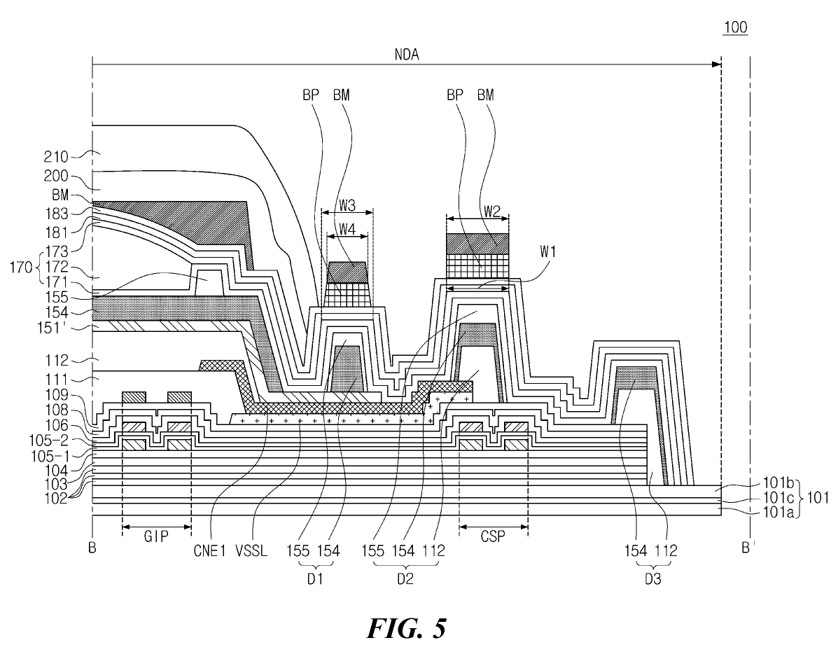

FIG. 5 is a cross-sectional view along line B-B′ in FIG. 1.

Referring to FIG. 5, at least one of the panel inorganic layers 102, 103, 104, 105-1, 105-2, 106, 108, and 109 may not extend to an end of the substrate 101. That is, the at least one of the panel inorganic layers 102, 103, 104, 105-1, 105-2, 106, 108, and 109 may expose the end of the substrate 101, but various embodiments of the present specification are not limited thereto.

The display panel 100 according to one embodiment may further include a crack sensing pattern CSP, a low-potential voltage line VSSL, and the gate driving unit GIP. As described above in FIG. 1, the low potential voltage line VSSL may be positioned between the crack sensing pattern CSP and the display area DA, and the gate driving unit GIP may be positioned between the low potential voltage line VSSL and the display area DA.

For example, as illustrated in FIG. 5, the gate driving unit GIP may be formed of a conductive layer positioned on the same layer as the first gate electrode 122 (see FIG. 3), a conductive layer positioned on the same layer as the second light-shielding layer 136 (see FIG. 3), or a conductive layer positioned on the same layer as the first source electrode 121, but various embodiments of the present specification are not limited thereto.

For example, the crack sensing pattern CSP may be disposed between a first dam D1 and a second dam D2. The crack sensing pattern CSP may be formed of a conductive layer positioned on the same layer as the first gate electrode 122 (see FIG. 3) or a conductive layer positioned on the same layer as the second light-shielding layer 136 (see FIG. 3), but various embodiments of the present specification are not limited thereto. For example, the crack sensing pattern CSP may include a conductive layer positioned on the same layer as the first source electrode 121, but various embodiments of the present specification are not limited thereto.

The low-potential voltage line VSSL may be disposed between the crack sensing pattern CSP and the gate driving unit GIP. The low-potential voltage line VSSL may be formed of a conductive layer positioned on the same layer as the first source electrode 121, but various embodiments of the present specification are not limited thereto.

The first protective layer 111 may cover the gate driving unit GIP, partially cover one end portion of the low-potential voltage line VSSL, and expose the other end portion of the low-potential voltage line VSSL. In the present specification, the one end portion may refer to an area of a certain component, which is positioned in a direction from the non-display area NDA toward the display area DA, and the other end portion may refer to an area of the certain component, which is positioned in a direction from the display area DA toward the non-display area NDA.

A first connection electrode CNE1 positioned on the same layer as the connection electrode 145 may be disposed on the first protective layer 111. The first connection electrode CNE1 may be directly connected to an area of the low-potential voltage line VSSL, in which the first protective layer 111 is exposed. The first connection electrode CNE1 may cover the other end portion of the low-potential voltage line VSSL, but various embodiments of the present specification are not limited thereto.

The second protective layer 112 may be disposed on the first connection electrode CNE1. The second protective layer 112 may be in direct contact with and cover one end portion of the first connection electrode CNE1 and expose the other end portion of the first connection electrode CNE1. The second protective layer 112 may form a first layer of the second dam D2 and a first layer of a third dam D3. The second dam D2 may be disposed between the first dam D1 and the third dam D3 and may overlap the crack sensing pattern CSP, but various embodiments of the present specification are not limited thereto. The first dam D1 may be disposed between the second dam D2 and the gate driving unit GIP, but various embodiments of the present specification are not limited thereto.

The first dam D1 may overlap, for example, the low-potential voltage line VSSL and cover the other end portion of the low-potential voltage line VSSL. The second dam D2 may be in direct contact with the first connection electrode CNE1 and cover the other end portion of the first connection electrode CNE1. The second protective layer 112 forming the first layer of the third dam D3 may be in direct contact with the exposed side surfaces of at least one of the panel inorganic layers 102, 103, 104, 105, 106, 107, and 109 and may be in direct contact with an upper surface of the substrate 101, but various embodiments of the present specification are not limited thereto. The second protective layer 112 may overlap the gate driving unit GIP. In the present specification, three dams are described as an example, but the number of dams may be one, two, or four or more.

A low-potential connection electrode 151′ positioned on the same layer as the first electrode 151 (see FIG. 3) may be disposed on the first connection electrode CNE1 exposed by the second protective layer 112 and the second protective layer 112. The low-potential connection electrode 151′ may be electrically connected to the first connection electrode CNE1 exposed by the second protective layer 112. The low-potential connection electrode 151′ may be electrically connected to the second electrode 153 (see FIG. 3) described above with reference to FIG. 3.

The bank 154 may be disposed on the low-potential connection electrode 151′ and the second protective layer 112. The bank 154 may overlap the gate driving unit GIP, overlap the low-potential connection electrode 151′, and cover the other end portion of the low-potential connection electrode 151′. The bank 154 may completely cover the low-potential connection electrode 151′, but various embodiments of the present specification are not limited thereto. The bank 154 may expose a central portion and the other end portion of the first connection electrode CNE1, but various embodiments of the present specification are not limited thereto. The bank 154 may include a first layer of the first dam D1, a second layer of the second dam D2, and a second layer of the third dam D3.

In each dam D2 or D3, the bank 154 may overlap the second protective layer 112 forming the first layer and completely cover the second protective layer 112, but various embodiments of the present specification are not limited thereto. In the third dam D3, the bank 154 may be in contact with side surfaces of the second protective layer 112 and the upper surface of the substrate 101, but various embodiments of the present specification are not limited thereto.

The spacer 155 may be disposed on the bank 154. The spacer 155 may be disposed on an upper surface of the bank 154 overlapping the gate driving unit GIP. The spacer 155 can prevent the second encapsulation layer 172 to be described below from overflowing. The spacer 155 may form third layers of the dams D2 and D3 and a second layer of the first dam D1. The spacer 155 forming the third layer of each of the dams D2 and D3 may overlap the bank 154 forming the second layer and completely cover the bank 154, but various embodiments of the present specification are not limited thereto. In the third dam D3, the spacer 155 may be in contact with side surfaces of the bank 154 and the upper surface of the substrate 101, but various embodiments of the present specification are not limited thereto. The spacer 155 forming the third layer of each of the dams D2 and D3 may overlap the bank 154 forming the first layer and completely cover the bank 154, but various embodiments of the present specification are not limited thereto.

The encapsulation part 170 may be disposed on the spacer 155. The first encapsulation layer 171 may extend to the gate driving unit GIP, the low-potential voltage line VSSL, and the first dam D1 to third dams D3 and cover an outer surface of the third dam D3. The second encapsulation layer 172 may terminate at the spacer 155 inside the first dam D1, as described above, or at the first dam D1. The second encapsulation layer 172 may overlap the gate driving unit GIP. The third encapsulation layer 173 may extend to the gate driving unit GIP, the low-potential voltage line VSSL, and the first dam D1 to the third dam D3 and may be in direct contact with the first encapsulation layer 171 on each of the first dam D1 to the third dam D3.

The touch buffer layer 181 and the first touch insulating layer 183 may extend to the gate driving unit GIP, the low-potential voltage line VSSL, and the first dam D1 to the third dam D3 and cover the outer surface of the third dam D3.

The black matrix BM may overlap the gate driving unit GIP and may also be disposed on the first dam D1 or the second dam D2. Widths of the black matrices BM on the dams D1 and D2 may be equal to, smaller than, or greater than widths of the dams D1 and D2.

Meanwhile, in the display panel 100 according to one embodiment, the island pattern BP described above with reference to FIG. 3 may be further disposed between the black matrix BM disposed on each of the dams D1 and D2 and each of the dams D1 and D2. That is, the black matrices BM may be disposed on upper surfaces of the island patterns BP on the dams D1 and D2. A width of the island pattern BP may be equal to the width of the black matrix BM, but various embodiments of the present specification are not limited thereto.

According to various embodiments of the present specification, heights of the dams D1 and D2 can be further increased by arranging the island pattern BP including the same material as the third color filter 193 (see FIG. 3) in the non-display area NDA. For example, as illustrated in FIG. 5, the island pattern BP and the black matrix BM are stacked on the first dam D1, thereby increasing a surface height compared to the existing first dam D1, and likewise, the island pattern BP and the black matrix BM are stacked on the second dam D2, thereby increasing a surface height compared to the existing first dam D1. In this way, when the surface heights are increased compared to the existing first and second dams D1 and D2, the second encapsulation layer 172, the planarization layer 200, or the upper insulating layer 210 can be prevented from overflowing the dams D1 and D2 and flowing to the outside of the display panel 100, thereby preventing physical interference between the display panel 100 and adjacent components and appearance defects.

The planarization layer 200 may be disposed on the black matrix BM. The planarization layer 200 may extend to the inside of the first dam D1 and may be in direct contact with the upper surface and side surfaces of the black matrix BM disposed on the spacer 155.

The upper insulating layer 210 may be disposed on the planarization layer 200. The upper insulating layer 210 may end at the first dam D1, but various embodiments of the present specification are not limited thereto.

In some embodiments, the black matrix BM may not be disposed on the island patterns BP on the dams D1 and D2.

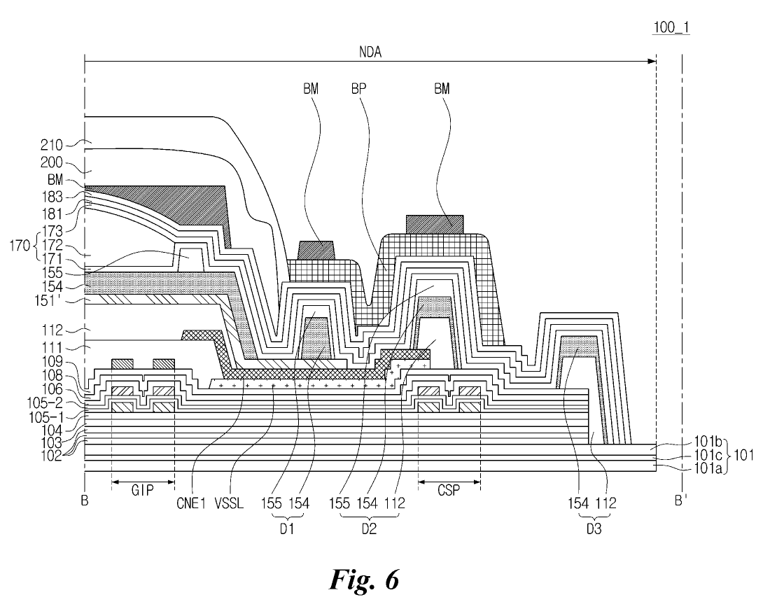

FIG. 6 is a cross-sectional view of the display panel according to another embodiment.

Referring to FIG. 6, a display panel 100_1 according to the present embodiment differs from the display panel 100 according to FIG. 5 in that the width of the island patterns BP disposed on the dams D1 and D2 is greater than the width of the black matrix BM.

More specifically, the island pattern BP may be continuously disposed between the first dam D1 and the second dam D2. The island pattern BP may also be disposed between the upper insulating layer 210 and the first dam D1 and between the first dam D1 and the second dam D2.

In some embodiments, the island patterns BP on the dams D1 and D2 and the island patterns BP disposed between the upper insulating layer 210 and the first dam D1 and between the first dam D1 and the second dam D2 may be disconnected.

Since the remaining parts have been described above with reference to FIG. 5, the detailed descriptions thereof will be omitted.

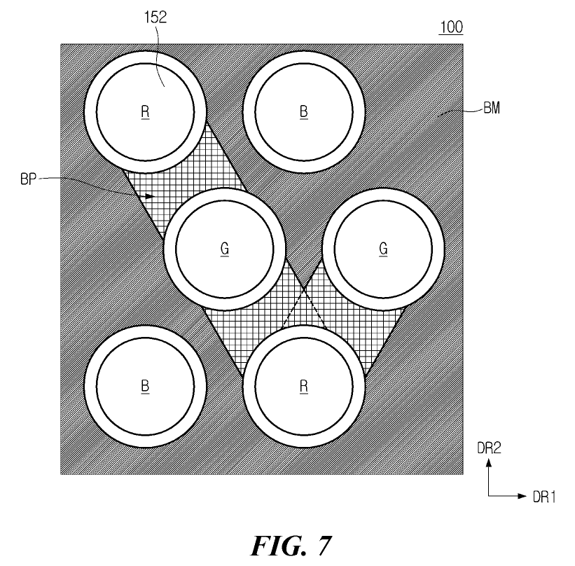

FIG. 7 is a plan view of a display panel according to one embodiment. FIG. 7 is a plan view of sub-pixels of the display panel 100 according to one embodiment. FIG. 7 illustrates the organic layers 152 (RGB) of the sub-pixels, and the black matrices BM and the island patterns BP disposed at the boundaries between the sub-pixels.

Referring to FIGS. 3 and 7, the organic layer 152 of the first sub-pixel PX1 (hereinafter referred to as an R organic layer) may be positioned on the upper left; the organic layer 152 of the third sub-pixel PX3 (hereinafter referred to as a B organic layer) may be positioned on the right side of the organic layer 152 of the first sub-pixel PX1; the organic layer 152 of the second sub-pixel PX2 (hereinafter referred to as a G organic layer) may be positioned diagonally below the R organic layer and the B organic layer; another G organic layer may be positioned on the right side of the G organic layer; the B organic layer may be positioned diagonally below the left side of the G organic layer; and the R organic layer may be positioned diagonally below the right side.

As described above with reference to FIG. 3, the black matrices BM or the island patterns BP may be disposed at the boundaries between the sub-pixels PX1, PX2, and PX3, the island pattern BP may be disposed in an area between the R organic layer and the G organic layer, and the black matrices BM may be disposed in an areas excluding the area between the R organic layer and the G organic layer.

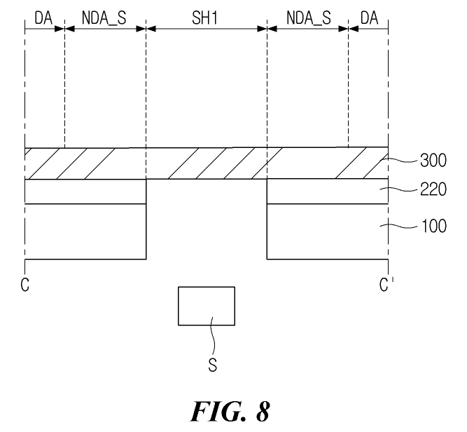

FIG. 8 is a cross-sectional view along line C-C′ in FIG. 1.

Referring to FIG. 8, as illustrated in FIG. 1, the display panel 100 may not be disposed in the sensor holes SH1 and SH2. That is, the sensor holes SH1 and SH2 may pass through the display panel 100. The sensor holes SH1 and SH2 may also pass through the bonding layer 220 on the display panel 100. A sensor S may be disposed in the first sensor hole SH1. For example, the sensor S may be an infrared sensor or a camera sensor, but various embodiments of the present specification are not limited thereto. As illustrated in FIG. 8, according to one embodiment, the bonding layer 220 having a gray-based color may be disposed in the sensor non-display area NDA_S, thereby improving visibility of circuits or lines disposed in the sensor non-display area NDA_S from the outside. In some embodiments, the bonding layer 220 having a gray-based color and a light-shielding material (e.g., a black matrix) may be disposed in the sensor non-display area NDA_S in a stacked manner. For example, the light-shielding material (e.g., a black matrix) may be disposed in a printed form on a lower surface of the cover layer 300, but various embodiments of the present specification are not limited thereto.

In some embodiments, when a structure in which the sensor holes SH1 and SH2 described above with reference to FIG. 1 are not disposed and an infrared sensor or a camera sensor is disposed in the display area DA, unlike FIG. 8, the sensor non-display area NDA_S and the first sensor hole SH1 may not be disposed, and the display panel 100 and the bonding layer 220 may be integrally formed on the entire surface. The sensor S may be disposed to overlap the display area DA.

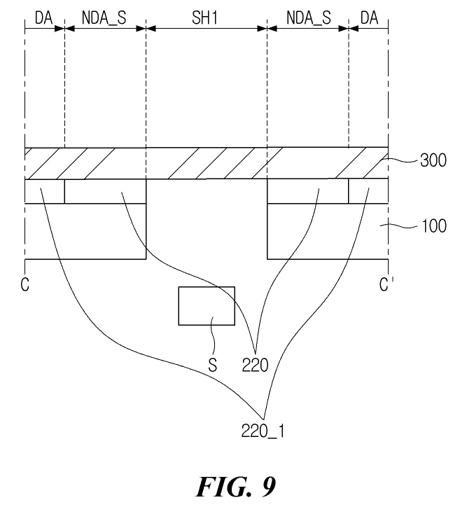

FIG. 9 is a cross-sectional view of a display device according to a modified example.

Referring to FIG. 9, the display device according to the present embodiment differs from the display device according to FIG. 8 in that the bonding layer 220 having a gray-based color described above with reference to FIG. 8 is disposed in the sensor non-display area NDA_S and a bonding layer 220_1 having a transparent-based color is disposed in the display area DA.

More specifically, the bonding layer 220_1 having a transparent-based color may be disposed in the display area DA, thereby increasing the light transmittance efficiency in the display area DA, and the bonding layer 220, which has a gray-based color and whose light transmittance is lower than that of the bonding layer 220_1, may be disposed in the sensor non-display area NDA_S, thereby improving the visibility of circuits or lines disposed in the sensor non-display area NDA_S from the outside.

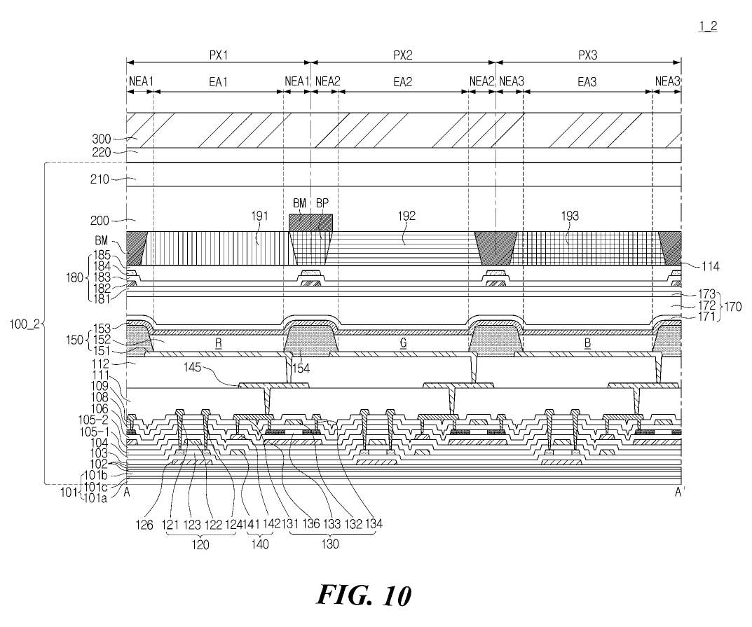

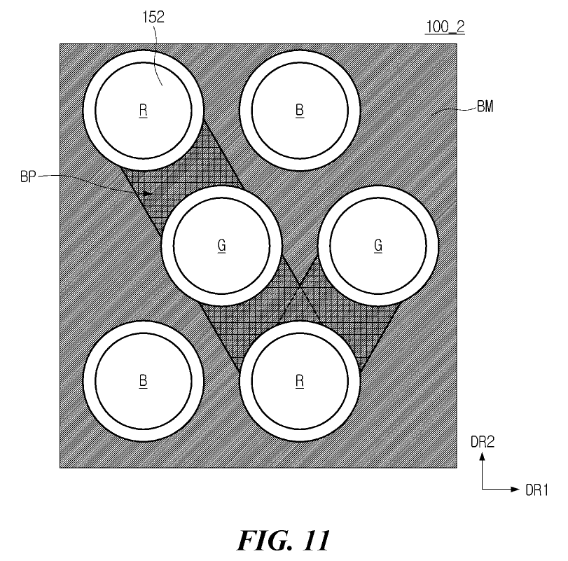

FIG. 10 is a cross-sectional view of a display device according to another embodiment. FIG. 11 is a plan view of the display panel according to another embodiment.

Referring to FIGS. 10 and 11, a display panel 100_2 of a display device 1_2 according to the present embodiment differs from the display device 1 according to FIG. 3 in that the black matrix BM is further disposed on the island pattern BP disposed at the boundary between the first sub-pixel PX1 and the second sub-pixel PX2.

The width of the black matrix BM and the width of the island pattern BP may be the same, but various embodiments of the present specification are not limited thereto.

According to the present embodiment, by further arranging the black matrix BM on the island pattern BP, light mixing and the entry of external light between adjacent first and second sub-pixels PX1 and PX2 can be prevented.

Since the remaining parts have been described above with reference to FIG. 3, the detailed descriptions thereof will be omitted.

As described above with reference to FIG. 3, the black matrices BM or the island patterns BP may be disposed at the boundaries between the sub-pixels PX1, PX2, and PX3, the island pattern BP may be disposed in an area between the R organic layer and the G organic layer, and the black matrices BM may be disposed in an areas excluding the area between the R organic layer and the G organic layer. Additionally, in the present embodiment, as illustrated in FIG. 11, the black matrix BM may be further disposed to overlap the island pattern BP.

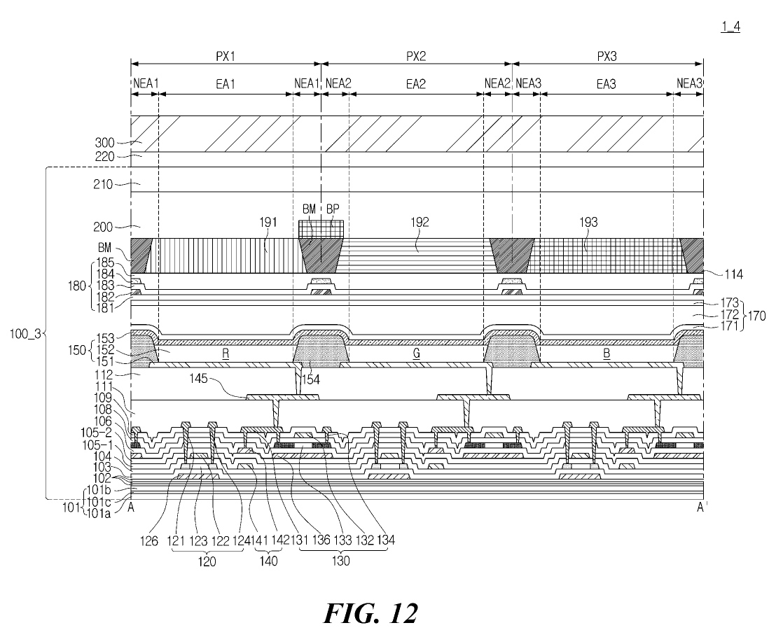

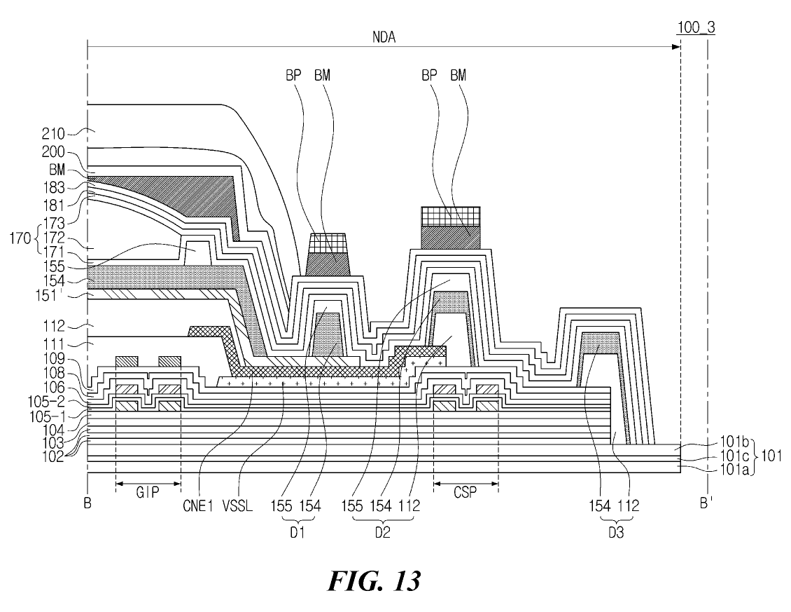

FIG. 12 is a cross-sectional view of a display device according to still another embodiment. FIG. 13 is a cross-sectional view of the display panel according to still another embodiment.

Referring to FIGS. 12 and 13, a display panel 100_3 of a display device 1_3 according to the present embodiment differs from the display device 1 according to FIG. 3 in that the black matrix BM is disposed at the boundary between the first sub-pixel PX1 and the second sub-pixel PX2 like the boundary between other sub-pixels, and the island pattern BP is disposed on the black matrix BM disposed at the boundary between the first sub-pixel PX1 and the second sub-pixel PX2.

More specifically, at the boundary between the first sub-pixel PX1 and the second sub-pixel PX2, the black matrix BM may be in direct contact with side surfaces of adjacent color filters 191 and 192, and the island pattern BP may be in direct contact with the upper surface of the black matrix BM at the boundary between the sub-pixels PX1 and PX2.

In the present embodiment, after the color filters 191, 192, and 193 are formed, the black matrix BM may be formed and may also be formed by the process of forming the island pattern BP.

In the present embodiment, the island pattern BP including the same material as the third color filter 193 may be stacked on the black matrix BM, thereby enhancing blue color reproduction.

Since the remaining parts have been described above with reference to FIG. 3, the detailed descriptions thereof will be omitted.

As illustrated in FIG. 13, meanwhile, in the case of the display panel 100_3 according to one embodiment, the black matrices BM may be disposed on the dams D1 and D2, and the island patterns BP may be disposed thereon. That is, the island patterns BP may be disposed on the upper surfaces of the black matrices BM on the dams D1 and D2.

The width of the island pattern BP may be equal to the width of the black matrix BM, but various embodiments of the present specification are not limited thereto.

According to various embodiments of the present specification, blue color reproduction can be enhanced by arranging the island pattern BP including the same material as the third color filter 193 (see FIG. 3) in the non-display area NDA.

Since the remaining parts have been described above with reference to FIG. 5, the detailed descriptions thereof will be omitted.

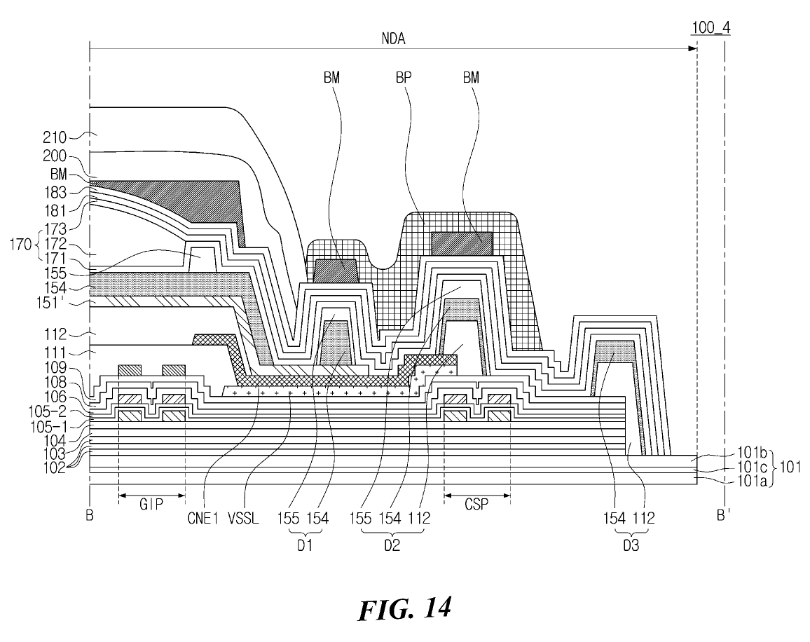

FIG. 14 is a cross-sectional view of a display panel according to yet another embodiment.

Referring to FIG. 14, a display panel 100_4 according to the present embodiment differs from the display panel 100_3 according to FIG. 13 in that the width of the island patterns BP disposed on the dams D1 and D2 is greater than the width of the black matrix BM.

More specifically, the island pattern BP may be continuously disposed between the first dam D1 and the second dam D2. The island pattern BP may also be disposed between the upper insulating layer 210 and the first dam D1 and between the first dam D1 and the second dam D2.

According to various embodiments of the present specification, blue color reproduction can be enhanced by increasing the width of the island pattern BP.

In some embodiments, the island patterns BP on the dams D1 and D2 and the island patterns BP disposed between the upper insulating layer 210 and the first dam D1 and between the first dam D1 and the second dam D2 may be disconnected.

Since the remaining parts have been described above with reference to FIGS. 5 and 13, the detailed descriptions thereof will be omitted below.

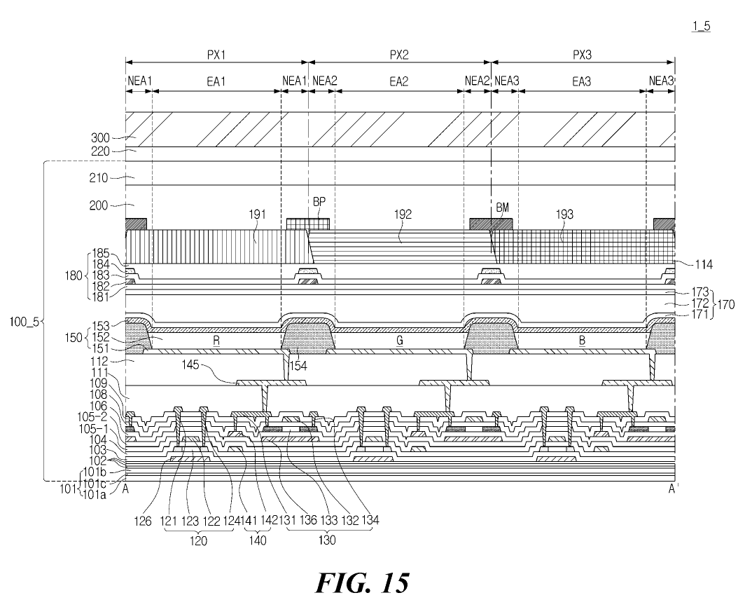

FIG. 15 is a cross-sectional view of a display device according to yet another embodiment.

Referring to FIG. 15, a display device 1_5 according to the present embodiment differs from the display device 1 according to FIG. 3 in that the color filters 191, 192, and 193 of the display panel 100_5 overlap each other at the boundaries between the sub-pixels PX1, PX2, and PX3. The cross-sectional view of FIG. 15 may be a cross-sectional view of the first sub-pixel PX1, the second sub-pixel PX2, and the third sub-pixel PX3 in the plan view of the display panel 100 described above with reference to FIG. 7.

More specifically, in the case of the present embodiment, for example, since the first color filter 191 is formed, the second color filter 192 is formed, and the third color filter 193 is formed, a structure in which the second color filter 192 overlaps the first color filter 191 and the third color filter 193 overlaps the second color filter 192 in the non-light-emitting area may be provided.

Even in the case of FIG. 15, the island pattern BP may be disposed at the boundary between the first sub-pixel PX1 and the second sub-pixel PX2, and the black matrices BM may be disposed at the boundary between the second sub-pixel PX2 and the third sub-pixel PX3 and the boundary between the third sub-pixel PX3 and the first sub-pixel PX1.

The island pattern BP may be in contact with the upper and side surfaces of the first color filter 191 and the second color filter 192, and the black matrix BM may be in contact with the side and upper surfaces of the second color filter 192, the side and upper surfaces of the third color filter 193, and the side and upper surfaces of the first color filter 191.

Since the remaining parts have been described above with reference to FIG. 3, the detailed descriptions thereof will be omitted.

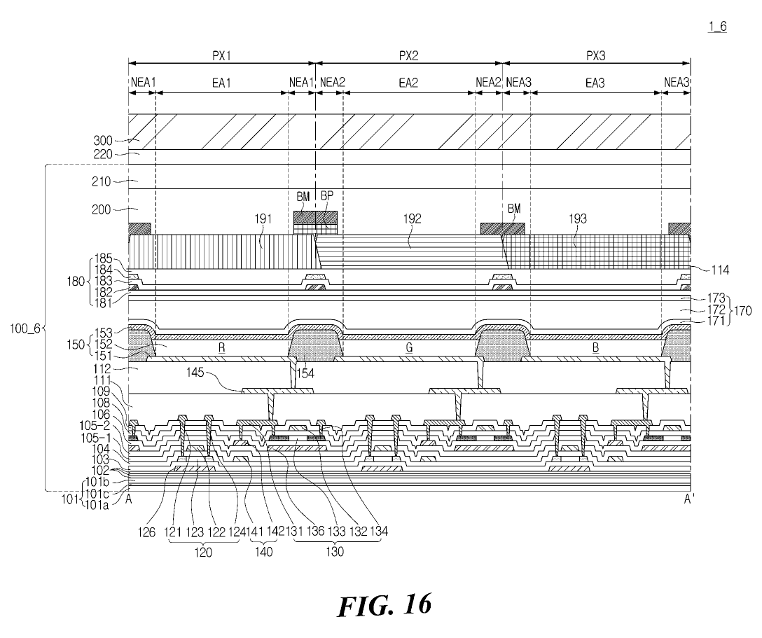

FIG. 16 is a cross-sectional view of a display device according to yet another embodiment.

Referring to FIG. 16, a display panel (100_6) of a display device 1_6 according to the present embodiment differs from the display device 1_5 according to FIG. 15 in that the black matrix BM is further disposed on the island pattern BP.

The cross-sectional view of FIG. 16 may be a cross-sectional view of the first sub-pixel PX1, the second sub-pixel PX2, and the third sub-pixel PX3 in the plan view of the display panel 100_2 described above with reference to FIG. 11. Since the remaining parts thereof have been described above with reference to FIGS. 3, 10, and 15, the detailed descriptions thereof will be omitted.

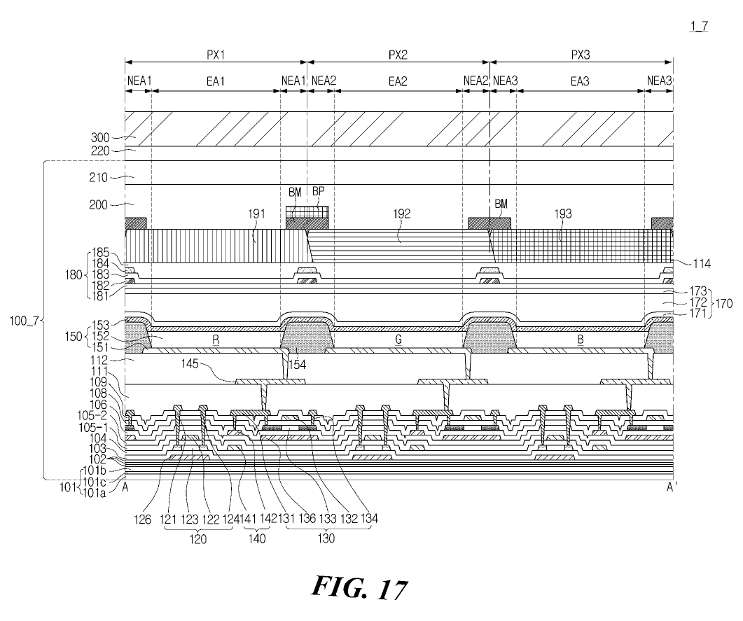

FIG. 17 is a cross-sectional view of a display device according to yet another embodiment.

Referring to FIG. 17, a display panel 100_7 of a display device 1_7 according to the present embodiment differs from the display device 1_5 according to FIG. 15 in that the black matrix BM is disposed at the boundary between the first sub-pixel PX1 and the second sub-pixel PX2 like the boundary between other sub-pixels, and the island pattern BP is disposed on the black matrix BM disposed at the boundary between the first sub-pixel PX1 and the second sub-pixel PX2.

The cross-sectional view of FIG. 17 may be a cross-sectional view of the first sub-pixel PX1, the second sub-pixel PX2, and the third sub-pixel PX3 in the plan view of the display panel 100_6 described above with reference to FIG. 16.

The black matrix BM disposed at the boundary between the first sub-pixel PX1 and the second sub-pixel PX2 may be in contact with the upper and side surfaces of the first color filter 191 and the upper and side surfaces of the second color filter 192.

Since the remaining parts have been described above in FIGS. 3, 12, and 15, the detailed descriptions thereof will be omitted below.

Further embodiments of the present disclosure are described below.

In some embodiments, as shown in FIGS. 1 and 3, a display device includes a display panel 100 having a display area (DA) and a non-display area (NDA) defined therein. The display device includes a plurality of color filters including a first color filter 191, a second color filter 192, and a third color filter 193. A black matrix (BM) may be disposed in both the display area and the non-display area.

As shown in FIG. 5, at least one dam (D1, D2) may be disposed in the non-display area, the at least one dam having an upper surface. An island pattern (BP) may be disposed in the display area and the non-display area, and the island pattern may include the same material as the third color filter 193. An organic layer (such as the second encapsulation layer 172, the planarization layer 200, the upper insulating layer 210, etc.) may be disposed on the display area and may extend into the non-display area. As shown in FIGS. 5 and 6, the island pattern and the black matrix are stacked on the upper surface of the at least one dam, thereby increasing a surface height of the dam and preventing the organic layer from overflowing outside the display panel 100.

As shown in FIG. 5, in some embodiments, the island pattern is disposed between the black matrix and the upper surface of the at least one dam. A width W1 of the island pattern may be equal to a width W2 of the black matrix. In other embodiments, as shown in FIG. 6, a width of the island pattern disposed on the at least one dam may be greater than a width of the black matrix disposed on the island pattern. FIG. 5 also shows a width W3 of the island pattern disposed on the at least one dam may be greater than a width W4 of the black matrix disposed on the island pattern.

In some embodiments, as shown in FIGS. 5 and 6, the at least one dam includes a plurality of dams including a first dam D1 and a second dam D2 spaced apart from the first dam. The island pattern may extend continuously and contiguously between the first dam and the second dam. In other embodiments, as shown in FIG. 13, the black matrix is disposed between the island pattern and the at least one dam, and the island pattern is disposed on an upper surface of the black matrix. In such configurations, as shown in FIG. 14, a width of the island pattern may be equal to or greater than a width of the black matrix.

As shown in FIG. 3, the display area includes a first sub-pixel PX1, a second sub-pixel PX2, and a third sub-pixel PX3. A light-emitting part 150 may be disposed in each of the first, second, and third sub-pixels, and a bank 154 may be disposed at boundaries between adjacent ones of the sub-pixels. The first color filter 191, the second color filter 192, and the third color filter 193 may be respectively disposed on the light-emitting parts of the sub-pixels.

In the display area, the black matrix may be disposed between selected adjacent ones of the color filters, and the island pattern may be disposed between selected adjacent ones of the color filters at a boundary at which the black matrix is omitted, specifically between the first and second sub-pixels. In some embodiments, a width W5 of the bank 154 is greater than a width W6 of the island pattern or a width W7 of the black matrix in the display area to increase the viewing angle.

In some embodiments, referring to a cross-sectional view as shown in FIGS. 3 and 5, the first color filter, the second color filter, and the third color filter may have a tapered shape. In the display area, the black matrix may have a reverse-tapered shape, and the island pattern may have a reverse-tapered shape because they are formed after the color filters. In the non-display area, as illustrated in the configurations of FIGS. 5 and 6, the black matrix may have a tapered shape, and the island pattern may have a tapered shape.

Additionally, a display device according to various embodiments of the present specification may be described as follows.

According to one embodiment, there is provided a display device including a substrate in which a display area including a first sub-pixel, a second sub-pixel, and a third sub-pixel, and a non-display area around the display area are defined, a light-emitting part disposed in each of the first sub-pixel, the second sub-pixel, and the third sub-pixel on the substrate, a first color filter on the light-emitting part in the first sub-pixel, a second color filter on the light-emitting part in the second sub-pixel, and a third color filter on the light-emitting part in the third sub-pixel, black matrices disposed between the second color filter and the third color filter and between the third color filter and the first color filter, and an island pattern disposed between the first color filter and the second color filter, in which the island pattern includes the same material as the third color filter.

In the display device according to various embodiments of the present specification, the first color filter may be a red color filter, the second color filter may be a green color filter, and the third color filter may be a blue color filter.

In the display device according to various embodiments of the present specification, the light-emitting part may include a first electrode, an organic layer on the first electrode, and a second electrode on the organic layer and further include banks which are disposed at boundaries between adjacent sub-pixels and are disposed between the first electrode and the organic layer, and the bank may include a black-based material.

In the display device according to various embodiments of the present specification, a width of the bank may be greater than a width of the black matrix.

In the display device according to various embodiments of the present specification, a distance between the bank and the organic layer in a plan view may be smaller than a distance between the black matrix and the organic layer in a plan view.

The display device according to various embodiments of the present specification may further include a planarization layer on the first color filter, the second color filter, and the third color filter, in which the black matrix and the island pattern may be in direct contact with the planarization layer.

The display device according to various embodiments of the present specification may further include a cover layer on the planarization layer, and a bonding layer between the cover layer and the planarization layer, in which the bonding layer may have a gray-based color.

In the display device according to various embodiments of the present specification, a sensor hole and a sensor non-display area between the sensor hole and the display area may be further defined, and the bonding layer may be disposed in the sensor non-display area.

In the display device according to various embodiments of the present specification, the island patterns may be in direct contact with side surfaces of the adjacent first color filter and side surfaces of the adjacent second color filter.

In the display device according to various embodiments of the present specification, the first color filter, the second color filter, and the third color filter may be disposed to be spaced apart from each other.

In the display device according to various embodiments of the present specification, the first color filter and the second color filter may overlap each other at a boundary between the first sub-pixel and the second sub-pixel, the second color filter and the third color filter may overlap each other at a boundary between the second sub-pixel and the third sub-pixel, and the third color filter and the first color filter may overlap each other at a boundary between the third sub-pixel and the first sub-pixel.

In the display device according to various embodiments of the present specification, the island patterns may be in contact with an upper surface and side surfaces of the first color filter, and an upper surface and side surfaces of the second color filter.

In the display device according to various embodiments of the present specification, the black matrix may be further disposed on an upper surface of the island pattern.

In the display device according to various embodiments of the present specification, the black matrix may be further disposed between the first color filter and the second color filter, and the island pattern may be disposed on an upper surface of the black matrix disposed between the first color filter and the second color filter.

The display device according to various embodiments of the present specification may further include a dam disposed in the non-display area on the substrate, and the island pattern may overlap the dam in the non-display area.

In the display device according to various embodiments of the present specification, the black matrix may be disposed on the upper surface of the island pattern in the non-display area.

In the display device according to various embodiments of the present specification, the black matrix may be disposed between the island pattern and the dam in the non-display area.

In the display device according to various embodiments of the present specification, the dam may be provided as a plurality of dams, and the island pattern may be disposed to extend between the plurality of dams.

According to various embodiments of the present specification, the opening region can be increased by forming the color filters and arranging the black matrices or the island patterns at the boundaries between the sub-pixels.

According to various embodiments of the present specification, diffraction due to external light can be prevented by forming the color filters and arranging the black matrices or the island patterns at the boundaries between the sub-pixels.

According to various embodiments of the present specification, the viewing angle can be increased by forming the color filters and arranging black matrices or the island patterns at the boundaries between the sub-pixels.

According to various embodiments of the present specification, the viewing angle can be increased by designing the width of the black matrix to be smaller than the width of the bank.

According to various embodiments of the present specification, the blue color reproduction can be enhanced by arranging the island pattern including the same material as the third color filter at the boundary between the first and second sub-pixels.

According to various embodiments of the present specification, the blue color reproduction can be increased by arranging the island pattern including the same material as the third color filter in the non-display area.

According to various embodiments of the present specification, external light reflection (or surface reflection) can be prevented by including the black material in the bank.

According to various embodiments of the present specification, the display device can be applied to flexible and foldable products by omitting the polarizing film.

According to various embodiments of the present specification, the low-power display device can be provided.

However, effects obtainable from the present specification are not limited to the above effects, and other effects that are not described will be able to be clearly understood by those skilled in the art to which the present specification pertains based on the following description.

Although various embodiments of the present disclosure have been described with reference to the accompanying drawings, it will be understood by those skilled in the art that the above-described technical configuration of the present disclosure may be implemented in other specific forms without changing the technical spirit or essential features of the present disclosure. Accordingly, it should be understood that the above-described embodiments are illustrative and not restrictive in all aspects. In addition, the scope of the present disclosure is described by the claims to be described below rather than the detailed description. In addition, the meaning and scope of the claims and all changed or modified forms derived from the equivalent concept should be construed as being included in the scope of the present disclosure.

### DESCRIPTION OF REFERENCE NUMERALS

1: display device
100: display panel
D1, D2, D3: dam
BM: black matrix
BP: island pattern

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area having a first sub-pixel, a second sub-pixel, and a third sub-pixel, and a non-display area adjacent to the display area;
a light-emitting part disposed in each of the first sub-pixel, the second sub-pixel, and the third sub-pixel on the substrate;
a first color filter on the light-emitting part in the first sub-pixel, a second color filter on the light-emitting part in the second sub-pixel, and a third color filter on the light-emitting part in the third sub-pixel;
a black matrix disposed between the second color filter and the third color filter and between the third color filter and the first color filter; and
an island pattern disposed between the first color filter and the second color filter,
wherein the island pattern includes the same material as the third color filter.

2. The display device of claim 1, wherein the first color filter is a red color filter, the second color filter is a green color filter, and the third color filter is a blue color filter, and
wherein the island pattern is configured to transmit blue light while blocking red and green light.

3. The display device of claim 1, wherein the light-emitting part includes a first electrode, an organic layer on the first electrode, and a second electrode on the organic layer, and the display device further includes a bank disposed at boundaries between adjacent sub-pixels and between the first electrode and the organic layer, and
wherein the bank includes a black-based material.

4. The display device of claim 3, wherein a width of the bank is greater than a width of the black matrix, or
wherein a width of the bank is greater than a width of the island pattern.

5. The display device of claim 3, wherein a distance in a plan view between an edge of the bank and an edge of the organic layer is smaller than a distance in a plan view between an edge of the black matrix and an edge of the organic layer.

6. The display device of claim 1, further comprising a planarization layer on the first color filter, the second color filter, and the third color filter, wherein the black matrix and the island pattern are in direct contact with the planarization layer.

7. The display device of claim 6, further comprising a cover layer on the planarization layer and a bonding layer between the cover layer and the planarization layer, wherein the bonding layer has a gray-based color.

8. The display device of claim 7, further comprising: a sensor hole and a sensor non-display area between the sensor hole and the display area, and the bonding layer is disposed in the sensor non-display area.

9. The display device of claim 1, wherein the island pattern is in direct contact with side surfaces of the adjacent first color filter and side surfaces of the adjacent second color filter.

10. The display device of claim 1, wherein the first color filter, the second color filter, and the third color filter are disposed to be spaced apart from each other.

11. The display device of claim 1, wherein the first color filter and the second color filter overlap each other at a boundary between the first sub-pixel and the second sub-pixel, the second color filter and the third color filter overlap each other at a boundary between the second sub-pixel and the third sub-pixel, and the third color filter and the first color filter overlap each other at a boundary between the third sub-pixel and the first sub-pixel.

12. The display device of claim 11, wherein the island pattern is in direct contact with an upper surface and side surfaces of the first color filter and an upper surface and side surfaces of the second color filter.

13. The display device of claim 1, wherein the black matrix is further disposed on an upper surface of the island pattern.

14. The display device of claim 1, wherein the black matrix is further disposed between the first color filter and the second color filter, and the island pattern is disposed on an upper surface of the black matrix disposed between the first color filter and the second color filter.

15. The display device of claim 1, further comprising a dam disposed in the non-display area on the substrate, wherein the island pattern overlaps the dam in the non-display area in a plan view.

16. The display device of claim 15, wherein the black matrix is disposed on an upper surface of the island pattern in the non-display area.

17. The display device of claim 15, wherein the black matrix is disposed between the island pattern and the dam in the non-display area.

18. The display device of claim 15, wherein the dam is provided as a plurality of dams, and the island pattern is disposed to extend between the plurality of dams.

19. A display device comprising:
a display panel including a display area and a non-display area defined therein;
a plurality of color filters including a first, second, and third color filter;
a black matrix disposed in the display area and the non-display area;
at least one dam disposed in the non-display area, the at least one dam having an upper surface;
an island pattern disposed in the display area and the non-display area, the island pattern including a same material as the third color filter;
an organic layer disposed on the display area and extending into the non-display area,
wherein the island pattern and the black matrix are disposed on the upper surface of the at least one dam,
wherein the island pattern and the black matrix are stacked on the upper surface of the at least one dam to increase a surface height of the at least one dam and to prevent the organic layer from overflowing outside the display panel.

20. The display device of claim 19, wherein the island pattern is between the black matrix and the upper surface of the at least one dam, a width of the island pattern is equal to a width of the black matrix.
